(19) United States
(12) Patent Application Publication
(10) Pub. No.: US 2025/0321063 A1
(43) Pub. Date: Oct. 16, 2025

(54) HOMOGENEOUS TEMPERATURE LIQUID-COOLING CONDENSER HEAT-DISSIPATING DEVICE

(71) Applicant: Winconn Systems INC., Taipei City (TW)

(72) Inventor: Jun LIN, Taipei City (TW)

(21) Appl. No.: 18/772,276

(22) Filed: Jul. 15, 2024

(30) Foreign Application Priority Data
Apr. 11, 2024 (CN) 202410435870.5

(51) Int. Cl. F28F 3/12; F28D 21/00; F28F 3/04

(52) U.S. Cl. CPC F28F 3/12; F28F 3/04; F28D 2021/0031; F28F 2220/00

(57) ABSTRACT

A homogeneous temperature liquid-cooling condenser heat-dissipating device includes side plates, an upper positioning plate, a lower positioning plate, water-cooling heat dissipation tubes, heat dissipation fins, a water-cooling heat dissipation assembly, and a vacuum heat dissipation assembly. The water-cooling heat dissipation assembly includes upper and lower water chambers and water inlet and outlet tubes. The vacuum heat dissipation assembly includes a vacuum box, vacuum guide tubes, and a vacuum heat absorption tube. The vacuum heat absorption tube is used to fast absorb heat and the heat passes sequentially through the vacuum box, the vacuum guide tubes, and the water-cooling heat dissipation tubes. Cold water in the water-cooling heat dissipation tubes absorbs the heat to fulfill temperature decreasing, and converts into warm water that is subjected to heat dissipation by the heat dissipation fins to convert to cold water, and thus circulating temperature decreasing is realized

### BACKGROUND OF THE INVENTION

### (a) Technical Field of the Invention

The present invention relates to the technical field of heat-dissipating equipment, and more particularly to a homogeneous temperature liquid-cooling condenser heat-dissipating device.

### (b) Description of the Prior Art

As the performance of various communication and industrial electronic products improves, the power of chips becomes larger and larger, and heat flow density becomes higher and higher, requiring dissipation of heat in order to ensure the release of the chip performance. With the performance heightened, the amount of heat induced by the chips gets larger, so that heat-dissipating devices play an important role in the electronic products. A known heat-dissipating device uses water cooling tubes and heat dissipation fins to take away heat. Heat is spread to the heat dissipation fins for conducting away the heat. Cold water inside the water cooling tubes brings the heat away from the heat dissipation fins. However, this way has a poor heat dissipation performance and normal operation of the chips may still be affected.

### SUMMARY OF THE INVENTION

An objective of the present invention is to provide a homogeneous temperature liquid-cooling condenser heat-dissipating device, aiming to resolve the technical issues of use that the heat dissipation performance of the prior art is poor and normal operation of a chip is affected.

To achieve the above objective, an embodiment of the present invention provides a homogeneous temperature liquid-cooling condenser heat-dissipating device, which comprises side plates, an upper positioning plate, a lower positioning plate, water-cooling heat dissipation tubes, heat dissipation fins, a water-cooling heat dissipation assembly, and a vacuum heat dissipation assembly, the upper positioning plate and the lower positioning plate being connected to ends of the side plates, the water-cooling heat dissipation tubes being connected to the upper positioning plate and the lower positioning plate, the heat dissipation fins being connected to one side of the water-cooling heat dissipation tubes, the water-cooling heat dissipation assembly being connected to the upper positioning plate and the water-cooling heat dissipation tubes, the water-cooling heat dissipation assembly and the water-cooling heat dissipation tubes forming a water cooling circuit, the vacuum heat dissipation assembly being arranged between the water-cooling heat dissipation tubes and the lower positioning plate and connected to the water-cooling heat dissipation tubes, the vacuum heat dissipation assembly, the water-cooling heat dissipation tubes, and the water-cooling heat dissipation assembly being sequentially connected and in communication with each other to form a heat dissipation passage.

As an optional solution of the present invention, the water-cooling heat dissipation assembly comprises an upper water chamber, a lower water chamber, a water inlet tube, and a water outlet tube, the upper water chamber and the lower water chamber being fixedly connected, in sequence, to the upper positioning plate and being both connected to and in communication with the water-cooling heat dissipation tubes, the water inlet tube being fixedly connected to the upper water chamber, the water outlet tube being fixedly connected to the lower water chamber, the water inlet tube, the water-cooling heat dissipation tubes, and the water outlet tube being sequentially connected and in communication with each other to form a water cooling heat dissipation circuit.

As an optional solution of the present invention, the water-cooling heat dissipation tubes are arranged as plural ones, the plural water-cooling heat dissipation tubes being parallel to and opposite to each other and forming multiple rows of water-cooling heat dissipation tubes, the water-cooling heat dissipation tubes being fixedly connected to the upper positioning plate and the lower positioning plate, adjacent ones of the water-cooling heat dissipation tubes being spaced from each other.

As an optional solution of the present invention, the vacuum heat dissipation assembly comprises a vacuum box, vacuum guide tubes, and a vacuum heat absorption tube, the vacuum box being fixedly connected to the lower positioning plate, the vacuum guide tubes being arranged as plural ones and uniformly and fixedly connected to the vacuum box, the vacuum guide tubes corresponding, in number, to the water-cooling heat dissipation tubes and connected to and in communication with the water-cooling heat dissipation tubes, one end of the vacuum heat absorption tube being fixedly connected to the vacuum box and another end extending out of the vacuum box.

As an optional solution of the present invention, the vacuum heat dissipation assembly further comprises closure caps, the closure caps penetrating through the lower positioning plate to be connected to and in communication with one of the rows of the water-cooling heat dissipation tubes, the closure caps, the water-cooling heat dissipation tubes, and the vacuum guide tubes being sequentially connected and in communication with each other to form a sealed environment, the closure caps corresponding, in number, to the water-cooling heat dissipation tubes.

As an optional solution of the present invention, the side plates are arranged as two side plates and the two side plates are spaced from each other, and are parallel to and opposite to each other, the two side plates being both fixedly connected to the upper positioning plate and the lower positioning plate.

As an optional solution of the present invention, the upper positioning plate and the lower positioning plate are formed with a plurality of positioning holes, the water-cooling heat dissipation tubes being arranged between the upper positioning plate and the lower positioning plate and inserted into and fixed to the positioning holes.

As an optional solution of the present invention, the heat dissipation fins are arranged in a wavey shape, and the heat dissipation fins are arranged as plural ones, the plural heat dissipation fins being parallel to and opposite to each other and fixedly connected to the water-cooling heat dissipation tubes, adjacent ones of the heat dissipation fins being spaced from each other, the water-cooling heat dissipation tubes and the heat dissipation fins being sequentially arranged.

As an optional solution of the present invention, a water collection box is arranged at a bottom side of the lower positioning plate, the water collection box being fixedly connected to the lower positioning plate, the water-cooling heat dissipation tubes extending into the water collection box.

One or multiple technical solutions of the homogeneous temperature liquid-cooling condenser heat-dissipating device provided in the embodiment of the present invention at least has one of the following technical effects:

The homogeneous temperature liquid-cooling condenser heat-dissipating device provided in the application comprises side plates, an upper positioning plate, a lower positioning plate, water-cooling heat dissipation tubes, heat dissipation fins, a water-cooling heat dissipation assembly, and a vacuum heat dissipation assembly and uses the vacuum heat absorption tube to fast absorb heat, and the heat passes sequentially through the vacuum box, the vacuum guide tubes, and the water-cooling heat dissipation tubes. Cold water in the water-cooling heat dissipation tubes absorbs the heat to fulfill temperature decreasing, and the cold water, after absorbing the heat, converts into warm water, and the warm water is subjected to heat dissipation by means of the heat dissipation fins to fulfill fast temperature decreasing and converts into cold water to thereby achieve circulating temperature decreasing, showing an excellent effect of heat dissipation to effectively ensure normal operation of a chip.

### BRIEF DESCRIPTION OF THE DRAWINGS

FIG. 1 is a schematic structure diagram showing a homogeneous temperature liquid-cooling condenser heat-dissipating device provided by an embodiment of the present invention.

FIG. 2 is a schematic structure diagram showing the homogeneous temperature liquid-cooling condenser heat-dissipating device according to an embodiment of the present invention, with a water-cooling heat dissipation assembly omitted.

FIG. 3 is a schematic structure diagram showing a vacuum heat dissipation assembly and water-cooling heat dissipation tubes of the homogeneous temperature liquid-cooling condenser heat-dissipating device provided by an embodiment of the present invention.

FIG. 4 is a schematic structure diagram showing the vacuum heat dissipation assembly of the homogeneous temperature liquid-cooling condenser heat-dissipating device provided by an embodiment of the present invention.

FIG. 5 is a schematic structure diagram showing the water-cooling heat dissipation tubes and an upper positioning plate and a lower positioning plate provided by an embodiment of the present invention.

### DETAILED DESCRIPTION OF THE PREFERRED EMBODIMENTS

The following provides a detailed description of an embodiment of the present invention, and illustration of the embodiment is depicted in the attached drawings, in which from beginning to end, the same or similar reference signs indicate the same or similar element or element having the same or similar functionality. The embodiment described below with reference to the attached drawings is only illustrative, aiming to explain the embodiment of the present invention, and not to be construed as limiting to the present invention.

In the description of the embodiment of the present invention, it is understood that the terms “length”, “width”, “up”, “down”, “front”, “rear”, “left”, “right”, “vertical”, “horizontal”, “top”, “bottom”, “inside”, and “outside” indicating directional or positional relationship are interpreted according to the directional or positional relationship depicted in the drawings and are only adopted for easy illustration of the embodiment of the present invention and simplification of the description, and do not indicate or imply a device or element referred to thereby must have a specific direction or must be constructed and operated in a specific direction, and thus, should not be construed as limiting to the present invention.

Further, the terms “first” and “second” are used only for description purposes and are not construed as indicating or implying relative importance or implicitly suggest the number of a technical feature referred to thereby. Thus, a feature defined with “first” and “second” can explicitly or implicitly includes one or more such feature, unless otherwise specifically stated.

In the embodiment of the present invention, unless otherwise explicitly defined and set, the terms “mounting”, “interconnecting”, “connecting”, and “fixing” should be interpreted in a broad sense, such as being fixedly connected or being detachably connected, or being integrated together; or being mechanically connected or electrically connected; or being directly connected or being indirectly connected through an intermediate medium, or interiors of two elements being in communication with each other or two elements being of a relationship of acting on each other. For those having ordinary knowledge of the technical field, the specific meaning of such terms as used in the embodiment of the present invention can be appreciated according to practical conditions.

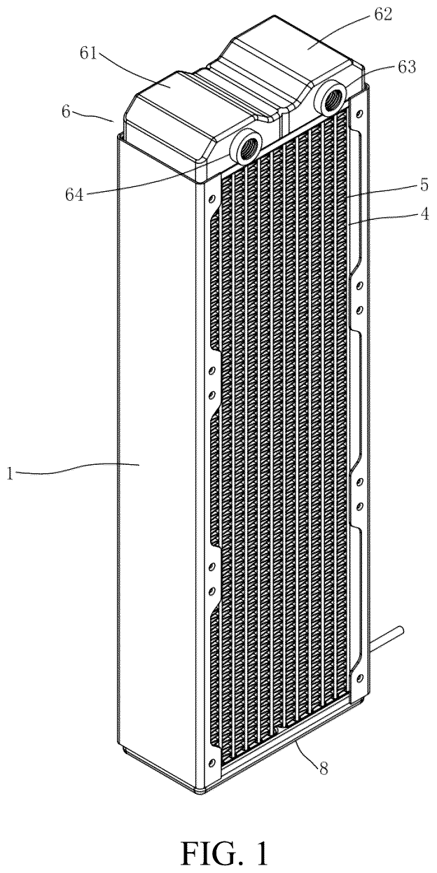

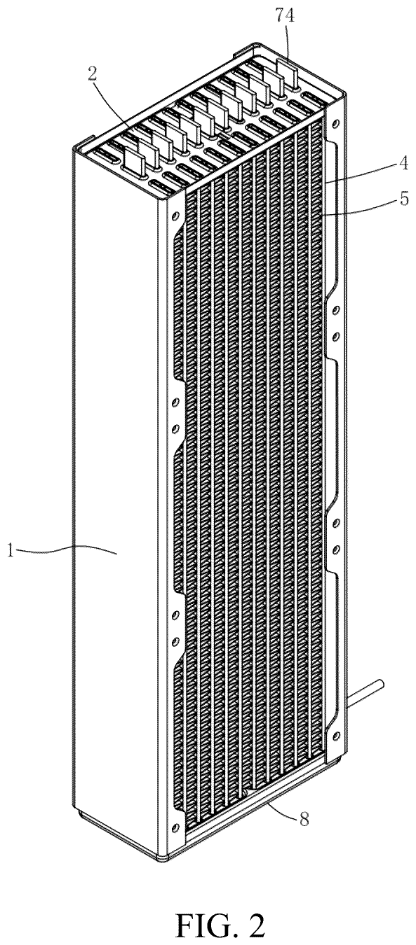

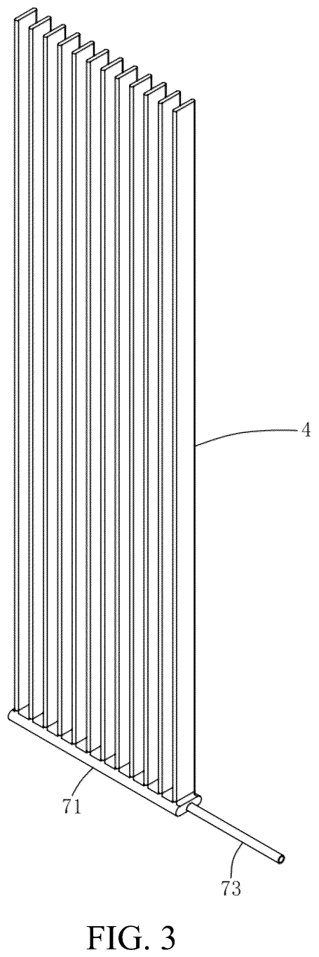

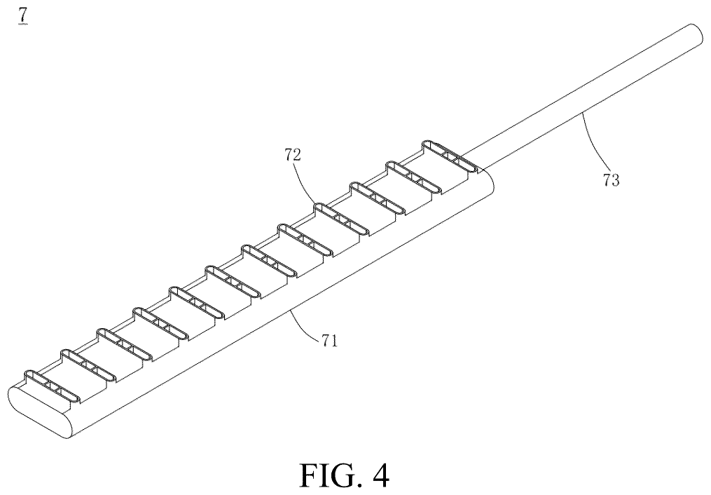

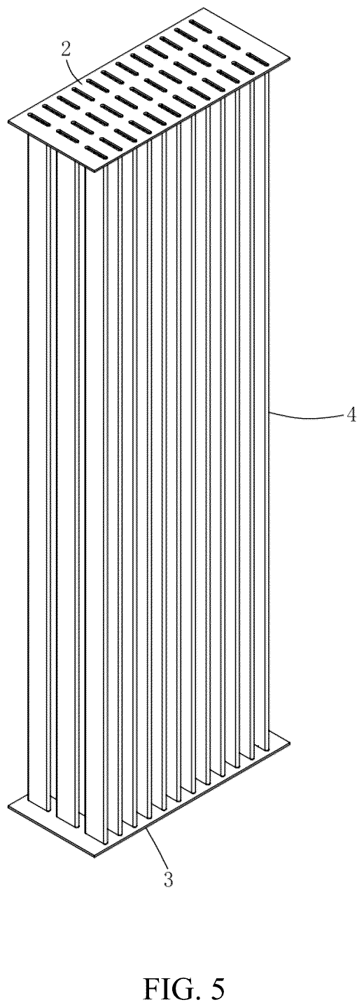

In an embodiment of the present invention, as shown in FIGS. 1-5, a homogeneous temperature liquid-cooling condenser heat-dissipating device is provided, comprising side plates 1, an upper positioning plate 2, a lower positioning plate 3, water-cooling heat dissipation tubes 4, heat dissipation fins 5, a water-cooling heat dissipation assembly 6, and a vacuum heat dissipation assembly 7. The upper positioning plate 2 and the lower positioning plate 3 are respectively fixedly connected to ends of the side plates 1. The water-cooling heat dissipation tubes 4 is fixedly connected to the upper positioning plate 2 and the lower positioning plate 3. The heat dissipation fins 5 are fixedly connected to one side of the water-cooling heat dissipation tubes 4. The water-cooling heat dissipation assembly 6 is fixedly connected to the upper positioning plate 2 and the water-cooling heat dissipation tubes 4, and the water-cooling heat dissipation assembly 6 and the water-cooling heat dissipation tubes 4 form a water cooling circuit, functioning for fast temperature decreasing. The vacuum heat dissipation assembly 7 is arranged between the water-cooling heat dissipation tubes 4 and the lower positioning plate 3, and is fixedly connected to the water-cooling heat dissipation tubes 4. The vacuum heat dissipation assembly 7, the water-cooling heat dissipation tubes 4, and the water-cooling heat dissipation assembly 6 are sequentially connected to form a heat dissipation passage. The homogeneous temperature liquid-cooling condenser heat-dissipating device provided in the application uses the vacuum heat absorption tube 73 to fast absorb heat, and the heat passes sequentially through a vacuum box 71, vacuum guide tubes 72, and the water-cooling heat dissipation tubes 4. Cold water in the water-cooling heat dissipation tubes 4 absorbs the heat to fulfill temperature decreasing, and the cold water, after absorbing the heat, converts into warm water, and the warm water is subjected to heat dissipation by means of the heat dissipation fins 5 to fulfill fast temperature decreasing and converts into cold water to thereby achieve circulating temperature decreasing, showing an excellent effect of heat dissipation to effectively ensure normal operation of a chip.

In another embodiment of the present invention, the water-cooling heat dissipation assembly 6 of the homogeneous temperature liquid-cooling condenser heat-dissipating device comprises an upper water chamber 61, a lower water chamber 62, a water inlet tube 63, and a water outlet tube 64. The upper water chamber 61 and the lower water chamber 62 are fixedly connected in sequence to the upper positioning plate 2 and are both connected to and in communication with the water-cooling heat dissipation tubes 4. The water inlet tube 63 is fixedly connected to the upper water chamber 61, and the water outlet tube is fixedly connected to the lower water chamber 62. The water inlet tube 63, the water-cooling heat dissipation tubes 4, and the water outlet tube 64 are sequentially connected and in communication with each other to form a water cooling heat dissipation circuit. The vacuum heat absorption tube 73 fast absorbs heat and transfers the heat to the water-cooling heat dissipation tubes 4, and cold water in the water-cooling heat dissipation tubes 4 absorbs the heat to fulfill temperature decreasing, and the cold water, after absorbing the heat, converts into warm water, and the warm water passes through the water inlet tube 63 to get into the upper water chamber 61, and the water in the upper water chamber 61 passes through the water-cooling heat dissipation tubes 4 to flow back to the lower water chamber 62 and is subjected to heat dissipation by means of the water-cooling heat dissipation tubes 4 and the heat dissipation fins 5 to fulfill fast decreasing of water temperature, and warm water is subjected to heat dissipation by means of the heat dissipation fins 5 to fulfill fast temperature decreasing and converts into cold water to get into the lower water chamber 62, and the cold water flows out through the water outlet tube 64, thereby achieving circulating temperature decreasing, showing an excellent effect of heat dissipation to effectively ensure normal operation of a chip.

In another embodiment of the present invention, the water-cooling heat dissipation tubes 4 of the homogeneous temperature liquid-cooling condenser heat-dissipating device are arranged as plural ones to enhance the heat dissipation efficiency. The plural water-cooling heat dissipation tubes 4 are arranged parallel and opposite to each other and are formed as multiple rows of water-cooling heat dissipation tubes 4. The water-cooling heat dissipation tubes 4 are fixedly connected to the upper positioning plate 2 and the lower positioning plate 3, and adjacent ones of the water-cooling heat dissipation tubes 4 are spaced from each other to increase the heat dissipation space for enhancing the heat dissipation efficiency.

In another embodiment of the present invention, the vacuum heat dissipation assembly 7 of the homogeneous temperature liquid-cooling condenser heat-dissipating device comprises a vacuum box 71, vacuum guide tubes 72, and a vacuum heat absorption tube 73. The vacuum box 71 is fixedly connected to the lower positioning plate 3. The vacuum guide tubes 72 are arranged as plural ones uniformly and fixedly connected to the vacuum box 71. The vacuum guide tubes 72 correspond, in number, to the water-cooling heat dissipation tubes 4 and are connected to and in communication with the water-cooling heat dissipation tubes 4. One end of the vacuum heat absorption tube 73 is fixedly connected to the vacuum box 71, and another end extends out of the vacuum box 71. The vacuum box 71 is evacuated to form a vacuum environment, and can fast absorb, through the vacuum heat absorption tube 73, the heat from a chip and transfers the heat to the water-cooling heat dissipation tubes 4, so that the water-cooling heat dissipation tubes 4 fast increases in temperature, and fast decreases temperature by means of cold water to enhance the heat dissipation efficiency.

In another embodiment of the present invention, the vacuum heat dissipation assembly 7 of the homogeneous temperature liquid-cooling condenser heat-dissipating device further comprises closure caps 74. The closure caps 74 penetrate through the lower positioning plate 3 to be connected to and in communication with one of the rows of the water-cooling heat dissipation tubes 4. The closure caps 74, the water-cooling heat dissipation tubes 4, and the vacuum guide tubes 72 are sequentially connected and in communication with each other and form a sealed environment. The closure caps 74 correspond, in number, to the water-cooling heat dissipation tubes 4.

In another embodiment of the present invention, the side plates 1 of the homogeneous temperature liquid-cooling condenser heat-dissipating device are arranged as two side plates, and the two side plates 1 are spaced from each other and are parallel to and opposite to each other. The two side plates 1 are both fixedly connected to the upper positioning plate 2, the lower positioning plate 3.

In another embodiment of the present invention, the upper positioning plate 2 and the lower positioning plate 3 of the homogeneous temperature liquid-cooling condenser heat-dissipating device are formed with a plurality of positioning holes. The water-cooling heat dissipation tubes 4 are arranged between the upper positioning plate 2 and the lower positioning plate 3 and are inserted into and fixed to the positioning holes.

In another embodiment of the present invention, the heat dissipation fins 5 of the homogeneous temperature liquid-cooling condenser heat-dissipating device are arranged in a wavey shape, and the heat dissipation fins 5 are arranged as plural ones to enhance the heat dissipation efficiency. The plural heat dissipation fins 5 are parallel to and opposite to each other and are fixedly connected to the water-cooling heat dissipation tubes 4. Adjacent ones of the heat dissipation fins 5 are spaced from each other. The water-cooling heat dissipation tubes 4 and the heat dissipation fins 5 are sequentially arranged.

In another embodiment of the present invention, a water collection box 8 is arranged at a bottom side of the lower positioning plate 3 of the homogeneous temperature liquid-cooling condenser heat-dissipating device, and the water collection box 8 is fixedly connected to the lower positioning plate 3, and the water-cooling heat dissipation tubes 4 extend into the water collection box 8. When the water-cooling heat dissipation tubes 4 get contact with hot air, due to a temperature difference, small water droplets condense and drop down along the water-cooling heat dissipation tubes 4 and are collected by the water collection box 8.

The homogeneous temperature liquid-cooling condenser heat-dissipating device provided in the application uses the vacuum heat absorption tube 73 to fast absorb heat, and the heat passes sequentially through a vacuum box 71, vacuum guide tubes 72, and the water-cooling heat dissipation tubes 4. Cold water in the water-cooling heat dissipation tubes 4 absorbs the heat to fulfill temperature decreasing, and the cold water, after absorbing the heat, converts into warm water, and the warm water is subjected to heat dissipation by means of the heat dissipation fins 5 to fulfill fast temperature decreasing and converts into cold water to thereby achieve circulating temperature decreasing, showing an excellent effect of heat dissipation to effectively ensure normal operation of a chip.

I claim:

1. A homogeneous temperature liquid-cooling condenser heat-dissipating device, comprising side plates, an upper positioning plate, a lower positioning plate, water-cooling heat dissipation tubes, heat dissipation fins, a water-cooling heat dissipation assembly, and a vacuum heat dissipation assembly, the upper positioning plate and the lower positioning plate being connected to ends of the side plates, the water-cooling heat dissipation tubes being connected to the upper positioning plate and the lower positioning plate, the heat dissipation fins being connected to one side of the water-cooling heat dissipation tubes, the water-cooling heat dissipation assembly being connected to the upper positioning plate and the water-cooling heat dissipation tubes, the water-cooling heat dissipation assembly and the water-cooling heat dissipation tubes forming a water cooling circuit, the vacuum heat dissipation assembly being arranged between the water-cooling heat dissipation tubes and the lower positioning plate and connected to the water-cooling heat dissipation tubes, the vacuum heat dissipation assembly, the water-cooling heat dissipation tubes, and the water-cooling heat dissipation assembly being sequentially connected and in communication with each other to form a heat dissipation passage.

2. The homogeneous temperature liquid-cooling condenser heat-dissipating device according to claim 1, wherein the water-cooling heat dissipation assembly comprises an upper water chamber, a lower water chamber, a water inlet tube, and a water outlet tube, the upper water chamber and the lower water chamber being fixedly connected, in sequence, to the upper positioning plate and being both connected to and in communication with the water-cooling heat dissipation tubes, the water inlet tube being fixedly connected to the upper water chamber, the water outlet tube being fixedly connected to the lower water chamber, the water inlet tube, the water-cooling heat dissipation tubes, and the water outlet tube being sequentially connected and in communication with each other to form a water cooling heat dissipation circuit.

3. The homogeneous temperature liquid-cooling condenser heat-dissipating device according to claim 1, wherein the water-cooling heat dissipation tubes are arranged as plural ones, the plural water-cooling heat dissipation tubes being parallel to and opposite to each other and forming multiple rows of water-cooling heat dissipation tubes, the water-cooling heat dissipation tubes being fixedly connected to the upper positioning plate and the lower positioning plate, adjacent ones of the water-cooling heat dissipation tubes being spaced from each other.

4. The homogeneous temperature liquid-cooling condenser heat-dissipating device according to claim 3, wherein the vacuum heat dissipation assembly comprises a vacuum box, vacuum guide tubes, and a vacuum heat absorption tube, the vacuum box being fixedly connected to the lower positioning plate, the vacuum guide tubes being arranged as plural ones and uniformly and fixedly connected to the vacuum box, the vacuum guide tubes corresponding, in number, to the water-cooling heat dissipation tubes and connected to and in communication with the water-cooling heat dissipation tubes, one end of the vacuum heat absorption tube being fixedly connected to the vacuum box and another end extending out of the vacuum box.

5. The homogeneous temperature liquid-cooling condenser heat-dissipating device according to claim 4, wherein the vacuum heat dissipation assembly further comprises closure caps, the closure caps penetrating through the lower positioning plate to be connected to and in communication with one of the rows of the water-cooling heat dissipation tubes, the closure caps, the water-cooling heat dissipation tubes, and the vacuum guide tubes being sequentially connected and in communication with each other to form a sealed environment, the closure caps corresponding, in number, to the water-cooling heat dissipation tubes.

6. The homogeneous temperature liquid-cooling condenser heat-dissipating device according to claim 1, wherein the side plates are arranged as two side plates and the two side plates are spaced from each other, and are parallel to and opposite to each other, the two side plates being both fixedly connected to the upper positioning plate and the lower positioning plate.

7. The homogeneous temperature liquid-cooling condenser heat-dissipating device according to claim 1, wherein the upper positioning plate and the lower positioning plate are formed with a plurality of positioning holes, the water-cooling heat dissipation tubes being arranged between the upper positioning plate and the lower positioning plate and inserted into and fixed to the positioning holes.

8. The homogeneous temperature liquid-cooling condenser heat-dissipating device according to claim 1, wherein the heat dissipation fins are arranged in a wavey shape, and the heat dissipation fins are arranged as plural ones, the plural heat dissipation fins being parallel to and opposite to each other and fixedly connected to the water-cooling heat dissipation tubes, adjacent ones of the heat dissipation fins being spaced from each other, the water-cooling heat dissipation tubes and the heat dissipation fins being sequentially arranged.

9. The homogeneous temperature liquid-cooling condenser heat-dissipating device according to claim 1, wherein a water collection box is arranged at a bottom side of the lower positioning plate, the water collection box being fixedly connected to the lower positioning plate, the water-cooling heat dissipation tubes extending into the water collection box.
